(19) United States
(12) Patent Application Publication
(10) Pub. No.: US 2024/0295027 A1
(43) Pub. Date: Sep. 5, 2024

(54) SUBSTRATE PROCESSING APPARATUS

(71) Applicant: Tokyo Electron Limited, Tokyo (JP)

(72) Inventors: Junnosuke TAGUCHI, Iwate (JP); Yasushi TAKEUCHI, Iwate (JP); Manabu HONMA, Iwate (JP); Ibuki HAYASHI, Iwate (JP)

(21) Appl. No.: 18/581,954

(22) Filed: Feb. 20, 2024

(30) Foreign Application Priority Data
Mar. 2, 2023 (JP) 2023-031907

(51) Int. Cl. C23C 16/458

(52) U.S. Cl. CPC C23C 16/4584

(57) ABSTRACT

A substrate processing apparatus includes a vacuum chamber; a rotary table rotatably provided in the vacuum chamber; and a stage configured to rotate together with the rotary table. The rotary table has an opening provided at a position spaced apart from a rotation center of the rotary table. An inner surface of the opening is continuous with an upper surface and a lower surface of the rotary table. The stage is spaced apart from the inner surface of the opening by a clearance.

### CROSS-REFERENCE TO RELATED APPLICATIONS

This patent application is based on and claims priority to Japanese Patent Application No. 2023-031907 filed on Mar. 2, 2023, the entire contents of which are incorporated herein by reference.

### TECHNICAL FIELD

The present disclosure relates to a substrate processing apparatus.

### BACKGROUND

An apparatus that deposits various films on a wafer by rotating a rotary table on which multiple wafers are mounted to cause the respective wafers to revolve and causing the wafers to repeatedly pass through process gas supply regions arranged along a radial direction of the rotary table is known (for example, see Patent Document 1). In the apparatus, while the wafer revolves with the rotary table, a stage of the wafer rotates so that the wafer rotates, thereby improving the uniformity of the film in a circumferential direction of the wafer.

### RELATED ART DOCUMENT

### Patent Document

[Patent Document 1] Japanese Laid-open Patent Application Publication No. 2021-111758

### SUMMARY

A substrate processing apparatus according to an aspect of the present disclosure includes a vacuum chamber; a rotary table rotatably provided in the vacuum chamber; and a stage configured to rotate together with the rotary table. The rotary table has an opening provided at a position spaced apart from a rotation center of the rotary table. An inner surface of the opening is continuous with an upper surface and a lower surface of the rotary table. The stage is spaced apart from the inner surface of the opening by a clearance.

### BRIEF DESCRIPTION OF THE DRAWINGS

FIG. 1 is a cross-sectional view illustrating a configuration example of a deposition apparatus according to an embodiment;

FIG. 2 is a plan view illustrating a configuration of an inside of a vacuum chamber of the deposition apparatus of FIG. 1;

FIG. 3 is a perspective view illustrating a configuration of a rotary table and a stage of the deposition apparatus illustrated in FIG. 1;

FIG. 4 is a sectional view illustrating a configuration of an inside of an accommodation box of the deposition apparatus of FIG. 1;

FIG. 5 is a plan view illustrating a stage;

FIG. 6 is a cross-sectional view taken along the line VI-VI of FIG. 5;

FIG. 7 is a cross-sectional view taken along the line VII-VII in FIG. 5;

FIG. 8 is a cross-sectional view taken along the line VIII-VIII of FIG. 5;

FIG. 9 is a cross-sectional view illustrating a rotary table in the related art;

FIG. 10 is a drawing illustrating a flow velocity distribution of a gas in the embodiment; and

FIG. 11 is a drawing illustrating a flow velocity distribution of a gas in a comparative example.

### DETAILED DESCRIPTION OF EMBODIMENTS

Non-restrictive exemplary embodiments of the present disclosure will be described below with reference to the accompanying drawings. In all the accompanying drawings, the same or corresponding members or parts are referenced by the same or corresponding reference symbols, and duplicated description will be omitted.

### [Substrate Processing Apparatus]

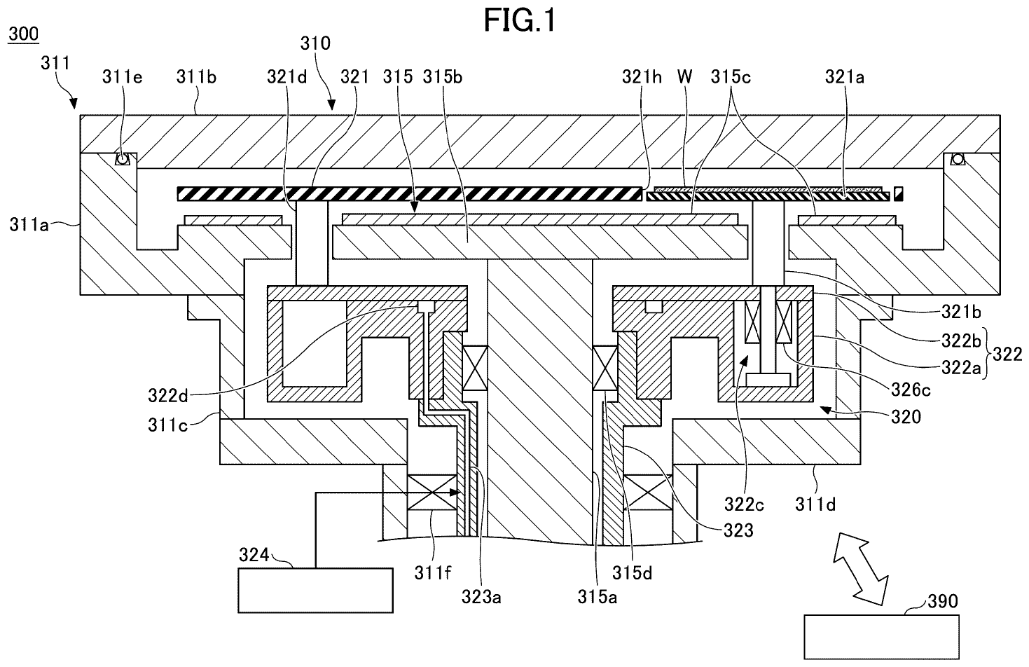

A deposition apparatus 300 that deposits a film on a substrate W will be described as an example of a substrate processing apparatus according to an embodiment with reference to FIG. 1 to FIG. 4.

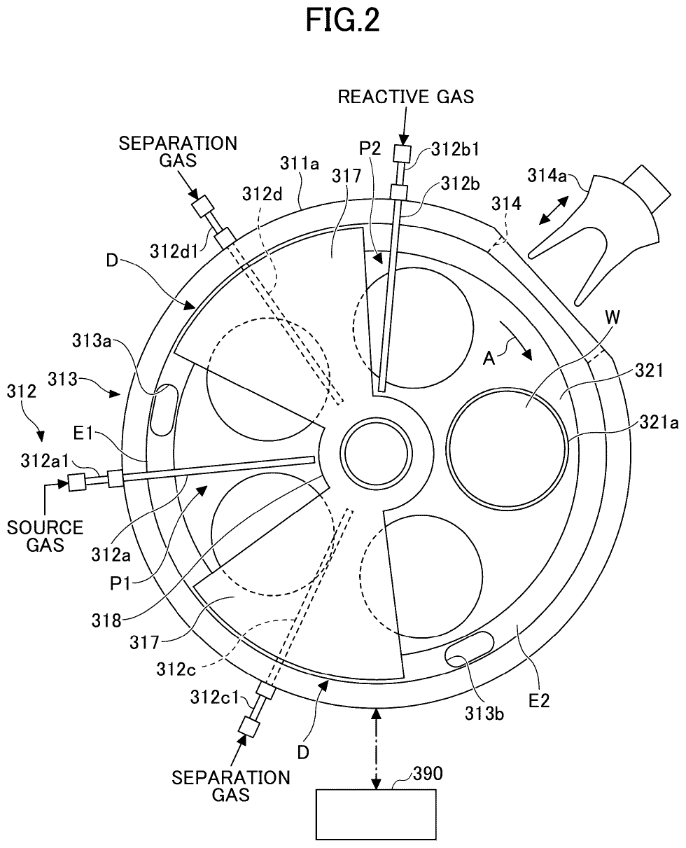

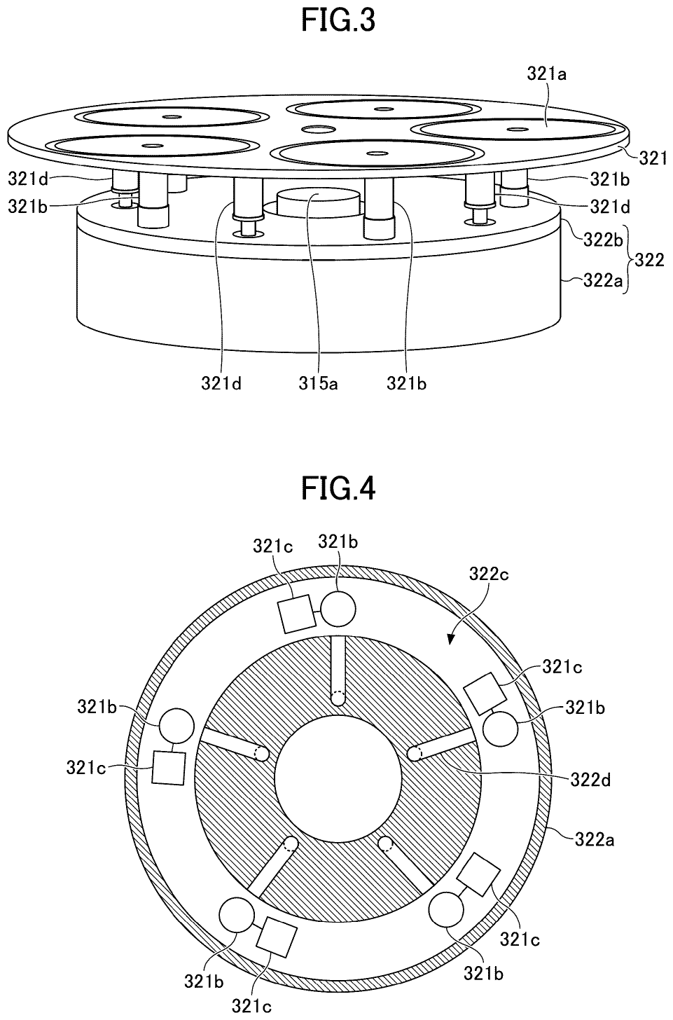

FIG. 1 is a cross-sectional view illustrating a configuration example of the deposition apparatus 300 according to the embodiment. FIG. 2 is a plan view illustrating a configuration of an inside of a vacuum chamber 311 of the deposition apparatus 300 of FIG. 1. In FIG. 2, for convenience of explanation, a top plate 311b is not illustrated. FIG. 3 is a perspective view illustrating a configuration of a rotary table 321 and a stage 321a of the deposition apparatus 300 of FIG. 1. FIG. 4 is a cross-sectional view illustrating a configuration of an inside of an accommodation box 322 of the deposition apparatus 300 of FIG. 1.

The deposition apparatus 300 includes a processing section 310, a rotary drive device 320, and a controller 390.

The processing section 310 includes the vacuum chamber 311, a gas introduction section 312, a gas exhaust port 313, a transfer port 314, and a heating section 315.

The vacuum chamber 311 is a processing chamber, the inside of which can be depressurized. The vacuum chamber 311 has a flat, substantially circular planar shape. The vacuum chamber 311 accommodates multiple substrates W inside. The substrate W may be, for example, a semiconductor wafer.

The vacuum chamber 311 includes a main body 311a, a top plate 311b, a sidewall body 311c, and a bottom plate 311d. The main body 311a has a cylindrical shape. The top plate 311b is detachably disposed on an upper surface of the main body 311a airtightly via a seal 311e. The sidewall body 311c is connected to a lower surface of the main body 311a and has a cylindrical shape. The bottom plate 311d is disposed airtightly with respect to a bottom surface of the sidewall body 311c.

The gas introduction section 312 includes a source gas nozzle 312a, a reactive gas nozzle 312b, and separation gas nozzles 312c and 312d. The source gas nozzle 312a, the reactive gas nozzle 312b, and the separation gas nozzles 312c and 312d are disposed above the rotary table 321 at intervals in a circumferential direction of the vacuum chamber 311 (a direction indicated by the arrow A in FIG. 2). In the illustrated example, the separation gas nozzle 312c, the source gas nozzle 312a, the separation gas nozzle 312d, and the reactive gas nozzle 312b are arranged in this order in a clockwise direction (a rotational direction of the rotary table 321) from the transfer port 314. Gas introduction ports 312a1, 312b1, 312c1, and 312d1, which are base ends of the source gas nozzle 312a, the reactive gas nozzle 312b, and the separation gas nozzles 312c and 312d, are fixed to an outer wall of the main body 311a. The source gas nozzle 312a, the reactive gas nozzle 312b, and the separation gas nozzles 312c and 312d are introduced into the vacuum chamber 311 from the outer wall of the vacuum chamber 311, and are attached to extend horizontally with respect to the rotary table 321 along a radial direction of the main body 311a. The source gas nozzle 312a, the reactive gas nozzle 312b, and the separation gas nozzles 312c and 312d are made of, for example, quartz.

The source gas nozzle 312a is connected to a source gas supply (not illustrated) via a pipe, a flow rate controller, and the like (not illustrated). As a source gas, for example, a silicon-containing gas or a metal-containing gas may be used. In the source gas nozzle 312a, multiple discharge holes (not illustrated) opened toward the rotary table 321 are arranged at intervals along a longitudinal direction of the source gas nozzle 312a. The source gas nozzle 312a discharges the source gas from the discharge holes. A region below the source gas nozzle 312a serves as a source gas adsorption region P1 for adsorbing the source gas onto the substrate W.

The reactive gas nozzle 312b is connected to a reactive gas supply (not illustrated) via a pipe, a flow rate controller, and the like (not illustrated). As a reactive gas, for example, an oxidizing gas or a nitriding gas can be used. In the reactive gas nozzle 312b, multiple discharge holes (not illustrated) opened toward the rotary table 321 are arranged at intervals along a longitudinal direction of the reactive gas nozzle 312b. The reactive gas nozzle 312b discharges the reactive gas from the discharge holes. A region below the reactive gas nozzle 312b serves as a reactive gas supply region P2 where the source gas adsorbed on the substrate W in the source gas adsorption region P1 is oxidized or nitrided.

The separation gas nozzles 312c and 312d are connected to a separation gas supply (not illustrated) via a pipe, a flow rate control valve, and the like (not illustrated). As a separation gas, for example, an inert gas, such as argon (Ar) gas or nitrogen (N₂) gas, can be used. In the separation gas nozzles 312c and 312d, multiple discharge holes (not illustrated) opened toward the rotary table 321 are arranged at intervals along longitudinal directions of the separation gas nozzles 312c and 312d. The separation gas nozzles 312c and 312d discharge the separation gas from the discharge holes.

The gas introduction section 312 may include a purge gas introduction section (not illustrated) configured to supply a purge gas below the rotary table 321. As the purge gas, for example, the same gas as the separation gas can be used.

Two protruding portions 317 are provided in the vacuum chamber 311. The protruding portions 317 are attached to a back surface of the top plate 311b so as to protrude toward the rotary table 321. The protruding portions 317 constitute separation regions D together with the separation gas nozzles 312c and 312d. The protruding portion 317 has a fan planar shape with a top portion being cut in an arc shape. An inner arc of the protruding portion 317 is connected to a protrusion 318. The protruding portion 317 is disposed such that an outer arc is along an inner wall of the main body 311a.

The gas exhaust port 313 includes a first exhaust port 313a and a second exhaust port 313b. The first exhaust port 313a is formed at a bottom of a first exhaust region E1. The first exhaust region E1 communicates with the source gas adsorption region P1. The second exhaust port 313b is formed at a bottom of a second exhaust region E2. The second exhaust region E2 communicates with the reactive gas supply region P2. The first exhaust port 313a and the second exhaust port 313b are connected to an exhaust device (not illustrated) including a vacuum pump and the like via an exhaust pipe (not illustrated).

The transfer port 314 is provided in the sidewall of the vacuum chamber 311. The transfer port 314 is an opening for transferring the substrate W between the rotary table 321 and a transfer arm 314a. The transfer port 314 is opened and closed by a gate valve (not illustrated).

The heating section 315 includes a fixed shaft 315a, a heater support 315b, and a heater 315c.

The fixed shaft 315a has a cylindrical shape having a central axis at the center of the vacuum chamber 311. The fixed shaft 315a is provided inside a rotary shaft 323 to penetrate the bottom plate 311d. A seal 315d is provided between an outer wall of the fixed shaft 315a and an inner wall of the rotary shaft 323. This allows the rotary shaft 323 to rotate with respect to the fixed shaft 315a while maintaining the airtight state in the vacuum chamber 311. The seal 315d includes, for example, a magnetic fluid seal.

The heater support 315b is fixed to an upper portion of the fixed shaft 315a and has a disk shape. The heater support 315b supports the heater 315c.

The heater 315c is provided on an upper surface of the heater support 315b. The heater 315c may be provided on the main body 311a in addition to the upper surface of the heater support 315b. The heater 315c heats the substrate W.

The rotary drive device 320 includes the rotary table 321, the accommodation box 322, the rotary shaft 323, and a revolution motor 324.

The rotary table 321 is provided in the vacuum chamber 311. The rotary table 321 has a rotation center at the center of the vacuum chamber 311. The rotary table 321 has, for example, a disk shape. The rotary table 321 is made of, for example, quartz. The rotary table 321 is connected to the accommodation box 322 via multiple connections 321d. The rotary table 321 has multiple (for example, five) openings 321h. The openings 321h are provided at intervals along a rotation direction of the rotary table 321. Each of the openings 321h is provided at a position spaced apart from the rotation center of the rotary table 321.

The stage 321a is provided at a position overlapping the opening 321h in plan view. Multiple stages 321a are provided along the rotation direction of the rotary table 321. The number of the stages 321a is equal to the number of the openings 321h. Each of the stages 321a is provided at a position spaced apart from the rotation center of the rotary table 321. Each of the stages 321a has a disk shape slightly larger than the substrate W. Each of the stages 321a is made of, for example, quartz. Each of the stages 321a may be made of a material having a high heat transfer rate, such as Al₂O₃, AlN, SiC or the like. The substrate W is mounted on each of the stages 321a. Each of the stages 321a is configured to be rotatable together with the rotary table 321. Each of the stages 321a is connected to a rotation motor 321c via a rotation shaft 321b and is configured to be rotatable with respect to the rotary table 321. The detailed configuration of the rotary table 321 and the stage 321a will be described later.

The rotation shaft 321b connects a lower surface of the stage 321a and the rotation motor 321c. The rotation shaft 321b transmits the power of the rotation motor 321c to the stage 321a. The rotation shaft 321b is configured to be rotatable using the center of the stage 321a as a rotation center. Multiple rotation shafts 321b are provided along the rotation direction of the rotary table 321. The number of the rotation shafts 321b is equal to the number of the stages 321a. The rotation shaft 321b penetrates through a ceiling 322b of the accommodation box 322. A seal 326c is provided in a through-hole of the ceiling 322b, and the inside of the accommodation box 322 is maintained in the airtight state. The seal 326c includes, for example, a magnetic fluid seal.

The rotation motor 321c is accommodated in the accommodation box 322. The rotation motor 321c rotates the stage 321a with respect to the rotary table 321 via the rotation shaft 321b. This allows the substrate W to rotate. The rotation motor 321c is, for example, a servo motor.

The connection 321d connects a lower surface of the rotary table 321 to an upper surface of the accommodation box 322. Multiple connections 321d are provided along a circumferential direction of the rotary table 321, for example. The connections 321d and the rotation shafts 321b may be provided on the same circumference. The connections 321d and the rotation shafts 321b may be alternately provided along the circumferential direction of the rotary table 321.

The accommodation box 322 is provided below the rotary table 321 in the vacuum chamber 311. The accommodation box 322 is connected to the rotary table 321 via the connections 321d and is configured to be rotatable integrally with the rotary table 321. The accommodation box 322 may be configured to be movable up and down in the vacuum chamber 311 by an elevating mechanism (not illustrated). The accommodation box 322 includes a main body 322a and the ceiling 322b.

The main body 322a is formed in a recessed shape in cross-sectional view and is formed in a ring shape along the rotation direction of the rotary table 321.

The ceiling 322b is provided on an upper portion of the main body 322a. The ceiling 322b closes an opening of the main body 322a formed in the recessed shape in cross-sectional view, so that the ceiling 322b and the main body 322a form an accommodation portion 322c isolated from the inside of the vacuum chamber 311.

The accommodation portion 322c is formed in a rectangular shape in a cross-sectional view and is formed in a ring shape along the rotation direction of the rotary table 321. The accommodation portion 322c accommodates the rotation motor 321c. A communication path 322d is formed in the main body 322a. The communication path 322d allows the accommodation portion 322c to communicate with the outside of the deposition apparatus 300. This introduces the air from the outside of the deposition apparatus 300 into the accommodation portion 322c through the communication path 322d. As a result, the inside of the accommodation portion 322c is cooled, and the inside of the accommodation portion 322c is maintained at the atmosphere pressure.

The rotary shaft 323 is fixed to a lower portion of the accommodation box 322. The rotary shaft 323 is provided to penetrate the bottom plate 311d. The rotary shaft 323 transmits the power of the revolution motor 324 to the rotary table 321 and the accommodation box 322, to cause the rotary table 321 and the accommodation box 322 to integrally rotate. A seal 311f is provided in a through-hole of the bottom plate 311d, and the airtight state in the vacuum chamber 311 is maintained. The seal 311f includes, for example, a magnetic fluid seal.

A through-hole 323a is provided inside the rotary shaft 323. The through-hole 323a is connected to the communication path 322d and functions as a fluid flow path for introducing the air into the accommodation box 322. The through-hole 323a also functions as a wire duct for introducing a power line and a signal line for driving the rotation motor 321c. The through-holes 323a equal in number to the number of the rotation motors 321c are provided, for example.

The controller 390 controls each section of the deposition apparatus 300. The controller 390 may be, for example, a computer. A computer program for performing an operation of each of the sections of the deposition apparatus 300 is stored in a storage medium. The storage medium may be, for example, a flexible disk, a compact disk, a hard disk, a flash memory, a digital versatile disk (DVD), or the like.

### [Stage]

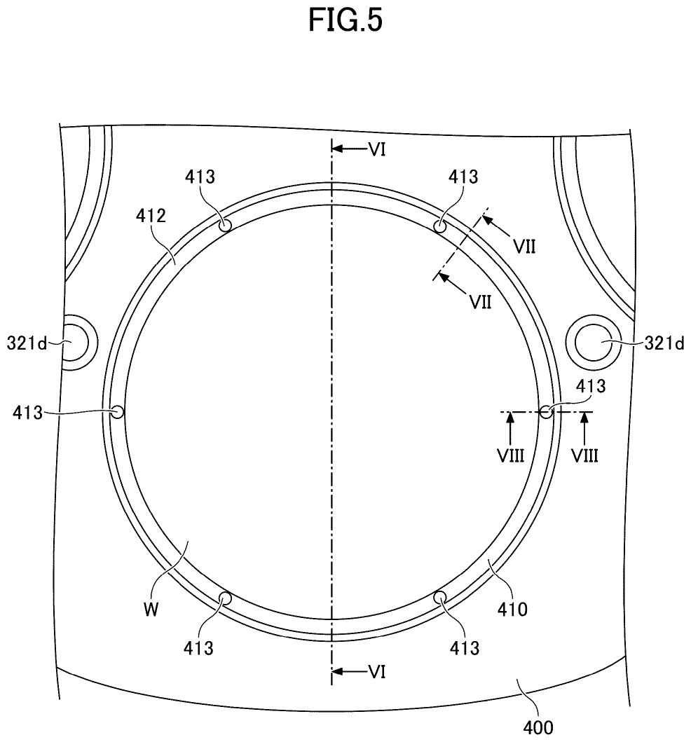

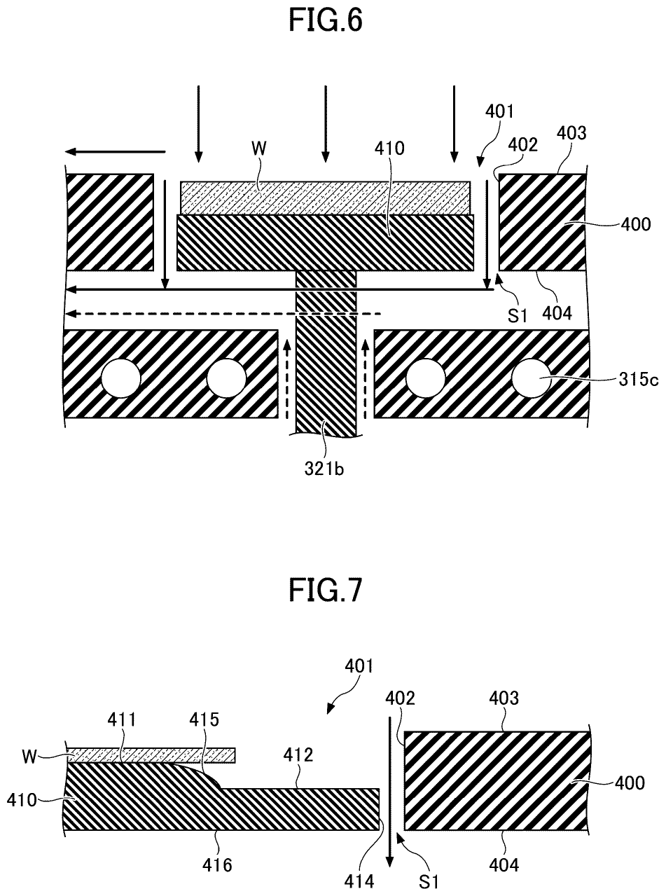

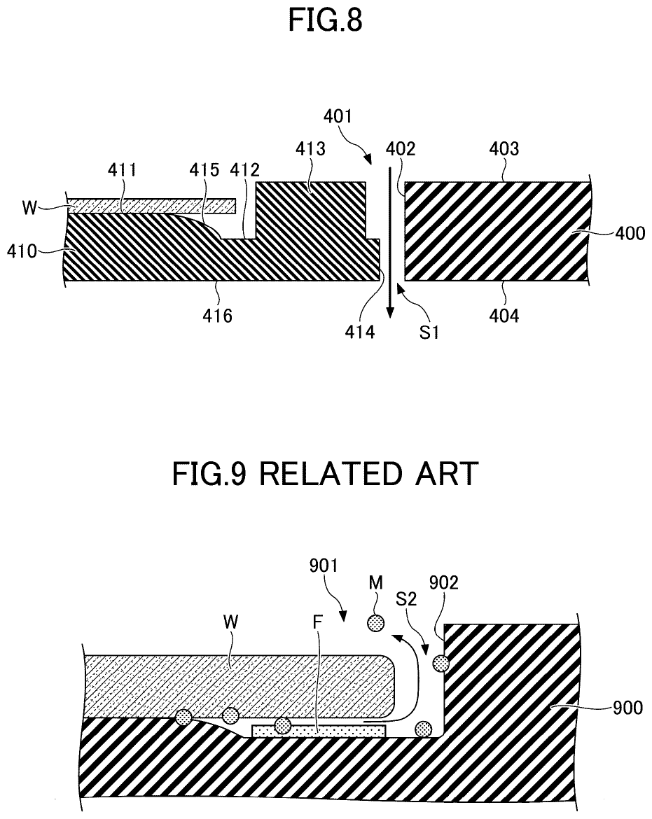

An example of the stage 321a included in the above-described deposition apparatus 300 will be described with reference to FIG. 5 to FIG. 8. Hereinafter, the rotary table 321 and the stage 321a will be respectively described as a rotary table 400 and a stage 410. FIG. 5 is a plan view illustrating the stage 410. FIG. 6 is a cross-sectional view taken along the line VI-VI of FIG. 5. FIG. 7 is a cross-sectional view taken along the line VII-VII of FIG. 5. FIG. 8 is a sectional view taken along the line VIII-VIII of FIG. 5. In FIG. 6, the flows of the source gas and the reactive gas are indicated by solid arrows, and the flow of the purge gas is indicated by a broken line. Hereinafter, the source gas and the reactive gas are collectively referred to as a process gas.

The rotary table 400 has multiple (for example, five) openings 401. The openings 401 are provided at intervals along the rotation direction of the rotary table 400. Each of the openings 401 is provided at a position spaced apart from the rotation center. An inner surface 402 of each of the openings 401 is continuous with an upper surface 403 and a lower surface 404 of the rotary table 400.

The stage 410 is provided at a position overlapping the opening 401 in plan view, apart from the inner surface 402 by a clearance S1. The clearance S1 extends from the upper side to the lower side of the rotary table 400 along the vertical direction. By providing the clearance S1, a gas flow directed downward below the stage 410 is formed at an outer periphery of the stage 410. The clearance S1 may be, for example, 0.1 mm or greater and 5 mm or less, and is preferably 2 mm. The substrate W is mounted on the stage 410. The stage 410 is connected to the rotation shaft 321b. The stage 410 rotates integrally with the rotation shaft 321b by the rotation of the rotation shaft 321b with respect to the rotary table 400.

The stage 410 includes a mounting surface 411, a recessed surface 412, a protrusion 413, a facing surface 414, an inclined surface 415, and a lower surface 416.

The mounting surface 411 forms an upper surface of the stage 410. The mounting surface 411 is provided at the center of the stage 410. The substrate W is mounted on the mounting surface 411. The mounting surface 411 is flat, for example. The height of the mounting surface 411 may be lower than the height of the upper surface 403 of the rotary table 400. The mounting surface 411 may have a circular shape having an outer diameter less than an outer diameter of the substrate W in plan view.

The recessed surface 412 forms an upper surface of the stage 410. The recessed surface 412 is provided on the stage 410 outside the mounting surface 411. The recessed surface 412 is recessed downward from the mounting surface 411. The recessed surface 412 is flat, for example. The recessed surface 412 may have an annular shape having an inner diameter less than the outer diameter of the substrate W and an outer diameter greater than the outer diameter of the substrate W in plan view.

The protrusion 413 is provided on at least a portion of the recessed surface 412. The protrusion 413 protrudes upward above the recessed surface 412. The protrusion 413 protrudes, for example, to a position higher than the mounting surface 411. The height of the protrusion 413 may be equal to the height of the upper surface 403 of the rotary table 400. By providing the protrusion 413, misalignment of the substrate W on the mounting surface 411 can be suppressed. The protrusion 413 has, for example, a columnar shape. Six protrusions 413 are provided at equal intervals along the circumferential direction of the stage 410, for example. However, the shape, the number, and the arrangement of the protrusions 413 are not limited thereto.

The facing surface 414 forms an outer surface of the stage 410. The facing surface 414 is continuous with an outer periphery of the recessed surface 412 and an outer periphery of the lower surface 416. The facing surface 414 is spaced apart from the inner surface 402 by the clearance S1 and faces the inner surface 402.

The inclined surface 415 forms an upper surface of the stage 410. The inclined surface 415 is provided between the mounting surface 411 and the recessed surface 412. The inclined surface 415 is continuous with the mounting surface 411 and the recessed surface 412. The inclined surface 415 is inclined downward from the mounting surface 411 toward the recessed surface 412. The inclined surface 415 may have an annular shape having an inner diameter and an outer diameter that are smaller than the outer diameter of the substrate W in plan view. By providing the inclined surface 415, friction between a back surface of an outer periphery of the substrate W and the stage 410 can be prevented. This can suppress generation of particles due to the friction between the substrate W and the stage 410. The inclined surface 415 is curved, for example.

The lower surface 416 is, for example, a flat surface. The lower surface 416 has a circular shape in plan view. The rotation shaft 321b is connected to the lower surface 416.

As described above, the deposition apparatus 300 according to the embodiment includes the vacuum chamber 311, the rotary table 400, and the stage 410. The rotary table 400 is rotatably provided in the vacuum chamber 311 and has an opening 401 provided at a position spaced apart from the rotation center. The opening 401 has the inner surface 402 continuous with the upper surface 403 and the lower surface 404. The stage 410 is provided apart from the inner surface 402 of the opening 401 by the clearance S1. In this case, the gas flow directed downward below the stage 410 is formed at the outer periphery of the stage 410.

When the gas flow directed downward below the stage 410 is formed at the outer periphery of the stage 410, remaining of the gas at the outer periphery of the stage 410 is suppressed. This can suppress adsorption of the source gas to the outer periphery of the stage 410 in the source gas adsorption region P1. Thus, bringing the source gas into the reactive gas supply region P2 when the stage 410 moves to the reactive gas supply region P2 by the rotation of the rotary table 400 is suppressed. Therefore, even when the reactive gas is supplied to the outer periphery of the stage 410 in the reactive gas supply region P2, a film is hardly deposited on the outer periphery of the stage 410. As a result, generation of particles due to the accumulation of the film can be suppressed.

Additionally, when the gas flow directed downward below the stage 410 is formed at the outer periphery of the stage 410, particles brought in by the transfer of the substrate W or the like can be removed by flowing the particles downward below the stage 410. Therefore, adhesion of particles to the substrate W mounted on the stage 410 can be suppressed.

With respect to the above, as illustrated in FIG. 9, in the case of a rotary table 900 having no opening 401, the process gas is likely to remain in a clearance S2 between an inner surface 902 of a recess 901 of the rotary table 900 and an outer end of the substrate W. Thus, the source gas is adsorbed on an outer periphery of the recess 901 in the source gas adsorption region P1, and when the recess 901 moves to the reactive gas supply region P2 by the rotation of the rotary table 900, the source gas is brought into the reactive gas supply region P2. Therefore, the supplied reactive gas reacts with the source gas adsorbed on the outer periphery of the recess 901 in the reactive gas supply region P2, and a film F is deposited on the outer periphery of the recess 901. A film deposited in the vacuum chamber 311 is removed by dry cleaning using a cleaning gas, but the cleaning gas is less likely to flow around the outer periphery of the recess 901 than the upper surface of the rotary table 900. Therefore, the film F deposited on the outer periphery of the recess 901 may remain without being removed, and may become a generation source of particles M.

### [Simulation Results]

In the deposition apparatus 300 including the rotary table 400 illustrated in FIG. 5 to FIG. 8, a simulation was performed on a flow velocity distribution of the gas supplied from the source gas nozzle 312a on the rotary table 400 (the embodiment). For comparison, in a deposition apparatus including the rotary table 900 illustrated in FIG. 9, a simulation was performed under the same conditions with respect to the flow velocity distribution of the gas supplied from the source gas nozzle 312a on the rotary table 900 (a comparative example).

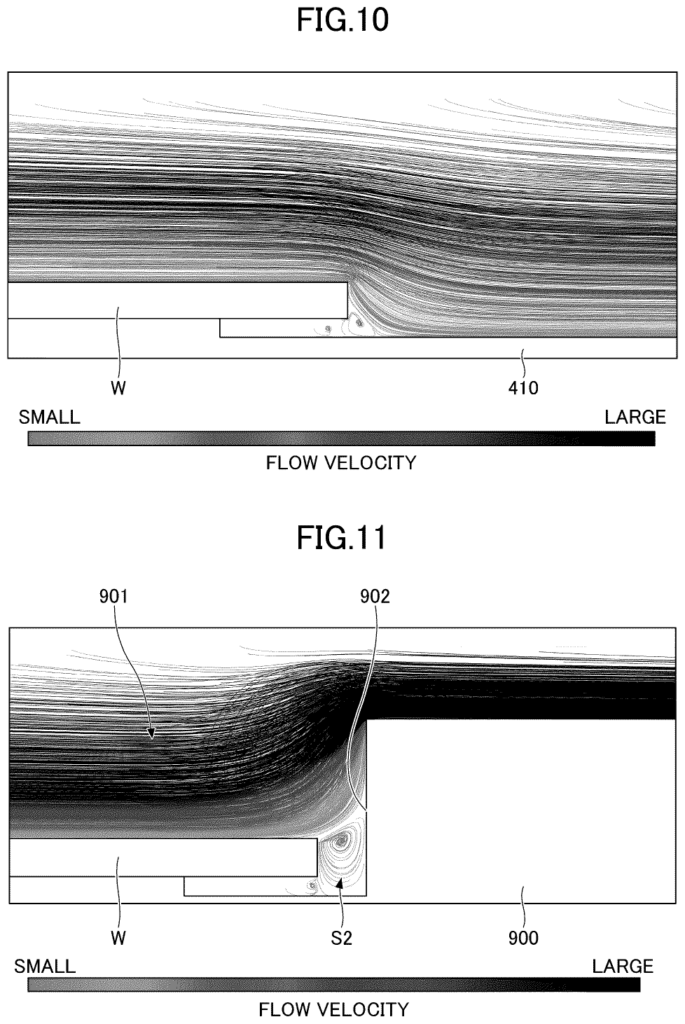

FIG. 10 is a drawing illustrating the flow velocity distribution of the gas in the embodiment. FIG. 11 is a drawing illustrating the flow velocity distribution of the gas in the comparative example.

As illustrated in FIG. 11, in the comparative example, it is found that the gas remains in the clearance S2 between the inner surface 902 of the recess 901 of the rotary table 900 and the outer end of the substrate W. With respect to the above, as illustrated in FIG. 10, in the embodiment, it is found that the gas hardly remains in the vicinity of the outer end of the substrate W in the embodiment. These results indicate that the remaining of the gas in the vicinity of the outer end of the substrate W can be suppressed by providing the stage 410 apart from the inner surface 402 of the opening 401 of the rotary table 400 by the clearance S1.

The embodiments disclosed herein are to be considered in all respects as illustrative and not restrictive. Omission, replacement, and modification may be made on the above-described embodiments in various forms without departing from the scope and spirit of the appended claims.

According to the present disclosure, generation of particles can be suppressed.

What is claimed is:

1. A substrate processing apparatus comprising:
a vacuum chamber;
a rotary table rotatably provided in the vacuum chamber; and
a stage configured to rotate together with the rotary table;
wherein the rotary table has an opening provided at a position spaced apart from a rotation center of the rotary table,
wherein an inner surface of the opening is continuous with an upper surface and a lower surface of the rotary table, and
wherein the stage is spaced apart from the inner surface of the opening by a clearance.

2. The substrate processing apparatus claimed in claim 1,
wherein the stage has:
a mounting surface provided at a center of the stage, a substrate being mounted on the mounting surface;
a recessed surface provided on the stage outside the mounting surface and recessed downward from the mounting surface; and
a facing surface continuous with the recessed surface, spaced apart from the inner surface of the opening by the clearance, and facing the inner surface of the opening.

3. The substrate processing apparatus claimed in claim 2, wherein the stage includes a protrusion provided on at least a portion of the recessed surface and protruding upward above the mounting surface.

4. The substrate processing apparatus claimed in claim 2, wherein the stage has an inclined surface provided between the mounting surface and the recessed surface and inclined from the mounting surface toward the recessed surface.

5. The substrate processing apparatus claimed in claim 2, wherein an outer diameter of the mounting surface is less than an outer diameter of the substrate.

6. The substrate processing apparatus claimed in claim 1, wherein the stage is rotatable with respect to the rotary table.
